(19) United States
(12) Patent Application Publication
(10) Pub. No.: US 2002/0132403 A1
(43) Pub. Date: Sep. 19, 2002

(54) Method of fabricating a self-align contact with a disposable spacer

(76) Inventors: Cheng-Yu Hung, Taipei (TW); Hsiao-Wen Lee, Hsinchu Hsien (TW); Ing-Ruey Liaw, Hsinchu (TW); Kuei-Chuen Ho, Hsinchu Hsien (TW)

Correspondence Address: Chun M. Ng, BLAKELY, SOKOLOFF, TAYLOR & ZAFMAN LLP, Seventh Floor, 12400 Wilshire Boulevard, Los Angeles, CA, 90025-1026, US

(21) Appl. No.: 10/045,295

(22) Filed: Oct. 18, 2001

Related U.S. Application Data
(62) Division of application No. 09/452,081, filed on Nov. 30, 1999, now abandoned.

(51) Int. Cl. H01L 21/337

(52) U.S. Cl. 438/186

(57) ABSTRACT

A gate structure is patterned on a substrate. An ion implantation is performed to form the LDD. Then, a thin liner layer is deposited on the feature of the substrate. A disposable spacer is successively formed attached on the side of the linear layer. The source and drain is next created in the substrate by ion implantation. The disposable spacer is then stripped by wet dip technique. A borderless layer is formed on the surface of the linear layer. A dielectric layer is formed on the gate structure and the dielectric layer can be composed of silicon dioxide, BPSG, SOG. Then, a photoresist is patterned on the dielectric layer to define the contact hole.

### FIELD OF THE INVENTION

The present invention relates to a method of fabricating a semiconductor device, in particular, to a method of fabricating a self-align contact by using disposable spacer. The present invention provides a larger process window in deep sub-micron MOSFET devices.

### DESCRIPTION OF THE PRIOR ART

Since semiconductor technologies were applied to manufacture integrated circuits (IC), IC designers always wish to create smaller scale, high speed and high-density devices at an ever fasten pace. In the past two decades, therefore, constantly striving to increase chip level and to reduce semiconductor device size become a trend in IC industry. As the packing density of devices increases and the spaces among devices become closer and closer, the devices manufactured in and on the semiconductor substrate, such as transistors and capacitors undoubtly have to be made smaller and smaller. The alignment and lithography technologies are naturally more important than ever because of the continuous shrinkage of semiconductor devices. The conventional self-aligned contact (SAC) technology is one of the technologies created to overcome the challenge. However, the tolence of the conventional SAC process will degrade as the contact dimension reduced.

When electronic devices continue shrinking to less than 0.18 micron-meter scale, the prior art meets a problem during the formation of self-align contact (SAC), as shown in FIG. 1. Gate oxide 3 and polysilicon gates 5 are formed on a semiconductor substrate 1. A metal salicide layer 5a is subsequently formed on the gate 5 to reduce the electric resistance. A cap layer 7 consisted of silicon nitride is then capped on the top surface of the gate structure. Typically, the cap layer 7 acts as an etching barrier for SAC etching to protect the gate from being etching. Lightly doped drain (LDD) 15 which is formed adjacent to the source and drain 13 to reduce the hot carrier effect. It can be formed by ion implantation either right after the formation of the caped gate, or after the formation of a thin oxide layer 9 attached on the side wall of the gate and the substrate. Side wall spacer 11, composed of silicon nitride formed on the side wall of the gate structure is used to form active regions 13, such as source and drain, are formed in the substrate 1 adjacent to the gate structure. A portion of the material for forming the spacer 11 may be on the upper surface of the cap layer 9 after the anisotropically etching to fabricate the spacer 11.

Turning to FIG. 2, a bordless silicon nitride 17 is conformally formed along the feature of aforementioned topography. The function of the bordless silicon nitride l7 includes protecting the shallow trench isolation area and improving the reliability of spacer 11 during SAC etching, as well as adjusting the wide of the subsequently formed contact holes. Next, a dielectric layer 19 is formed to cover the bordless nitride 17, gate structure, cap layer 7 and the side wall spacers 11, the dielectric layer can be formed of BPSG. A photoresist (not shown) is patterned on the dielectric layer 19. Then, a dry etching is performed to etch the dielectric layer 19 for forming contact hole 21 in the BPSG 19. The photoresist is then removed. A conductive material will fill into the contact hole 21, followed by a planarization by chemical mechanical polishing to form conductive plug therein.

Please turn to FIG. 3, in the conventional SAC process, the minimum spacing (indicated by d) between spacers is approximately equal to D-2 (W_{oxide}+W_{spacer}). Wherein D indicates the spacing between gate 5, W_{oxide} and W_{spacer} represent the widths of the oxide 9 and spacer 11, respectively. Under the current process parameters, the dimension of the D is less then 0.19 micron meter, the widths of the W_{oxide} and W_{spacer} are about or thicker than 100 and 400, respectively. In addition, if a bordless layer 17 is added to the prodess, the width of the contact hole 21 will be squeezed to less than 0.05 micron meter. The aspect ratio of the contact (a ratio of a contact depth to width) is about 9 (0.45/0.05). This order of the aspect ratio will create many difficulties in deep sub-micron process. For example, the squeezed contact hole impacts to the step of gap filling. It makes that it is hard to refill a material into the contact hole. Another issue is that the dielectric materials between the gates, especially the SiN spacers left in the structure, will worsen the problem relating to the parasitic capacitance. The stronger capacitor-coupling will increase the RC time delay caused by the parasitic capacitance of wiring. A stronger stress generated at nitride spacer corner is also discovered to be a main factor of the stress-induced substrate defects, which is a severe yield killer for IC manufacture.

What is required is a new method of forming a self-aligned contact for deep sub-micron MOSFET.

### SUMMARY OF THE INVENTION

It is an object of the present invention to provide a method for fabricating an integrated circuit having self align contact hole and that can overcome the problems of aforementioned.

It is another object of the present invention to provide a method of fabricating a self align contact with disposable spacer.

A gate oxide layer, a polysilicon layer and a cap nitride are respectively deposited on a substrate. Then, the gate oxide layer, the polysilicon layer and the silicon nitride layer are patterned to form a gate structure. Subsequently, a silicon dioxide layer is optionally formed on the surface of the gate and substrate by thermal process. The purpose of the oxide is to act as a buffer for LDD (lightly doped drain) implantation. An ion implantation is performed to form the LDD. Then, a thin liner layer is deposited on the feature of the substrate. The thickness of the liner is about 50 to 100 angstroms. The material for forming the linear layer is composed of nitride. A disposable spacer is successively formed attached on the side of the linear layer. Preferably, the material for the spacer exhibits the characteristic of easily removable. One of the candidates is an oxide formed by TEOS. The source and drain is next created in the substrate by ion implantation with higher dosage using the gate structure and spacer an implantation mask.

The disposable spacer is then stripped by wet dip technique using HF solution or BOE solution. The whole structure will return to the original structure before depositing the TEOS spacer. An optional step is next performed to form a borderless layer on the surface of the nitride layer. The borderless layer is used to make sure the gate will not be etched during the procedure of SAC etching. The thickness of the borderless nitride layer ranges from about 150 to 250 angstroms. A dielectric layer is formed on the gate structure and the dielectric layer can be composed of silicon dioxide, BPSG, SOG. Then, a photoresist is patterned on the dielectric layer to define the contact hole area.

### BRIEF DESCRIPTION OF THE DRAWINGS

FIG. 1 is a cross section view of a semiconductor wafer illustrating the step of forming a transistor according to prior art.

FIG. 2 is a cross section view of a semiconductor wafer illustrating the step of forming self-aligned contact (SAC) according to the prior art.

FIG. 3 is a cross section view of a semiconductor wafer illustrating the SAC structure according to the prior art.

FIG. 4 is a cross section view of a semiconductor wafer illustrating the step of forming a transistor according to the present invention.

FIG. 5 is a cross section view of a semiconductor wafer illustrating the step of forming self-aligned contact (SAC) with disposable spacer according to the present invention.

FIG. 6 is a cross section view of a semiconductor wafer illustrating the SAC structure according to the present invention.

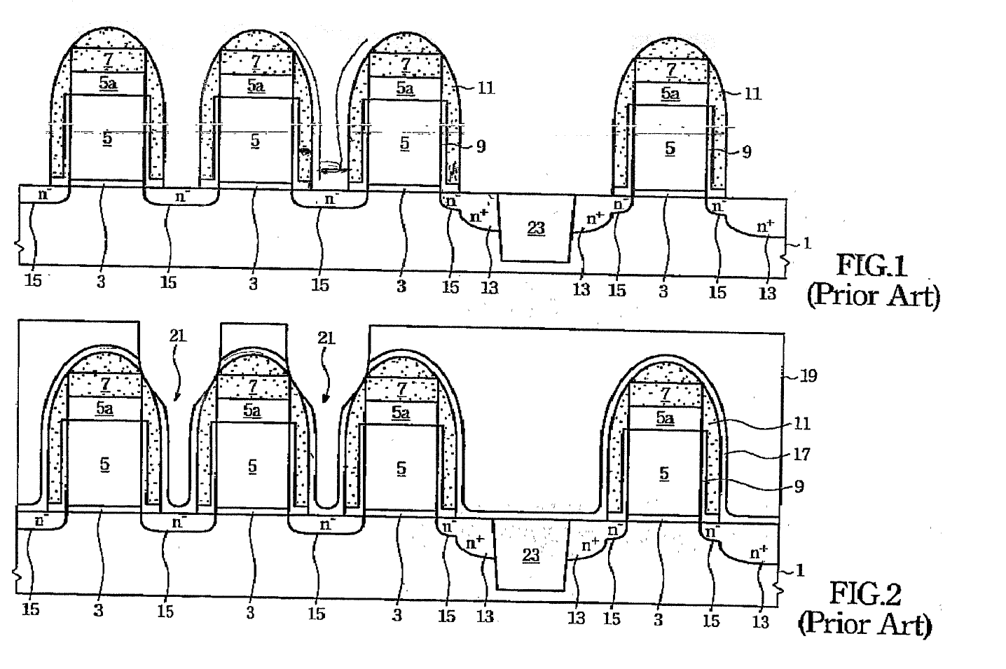

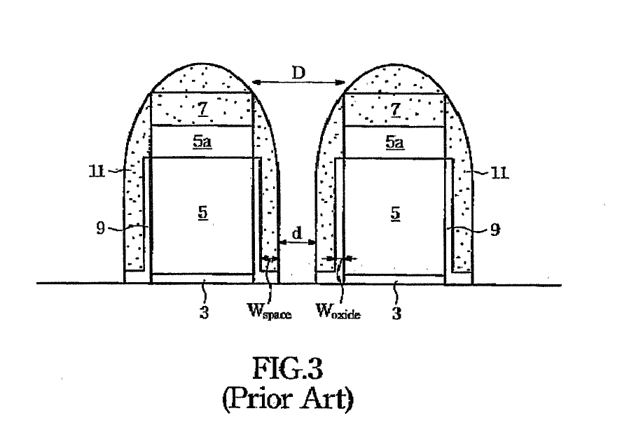

### DESCRIPTION OF THE PREFERRED EMBODIMENT

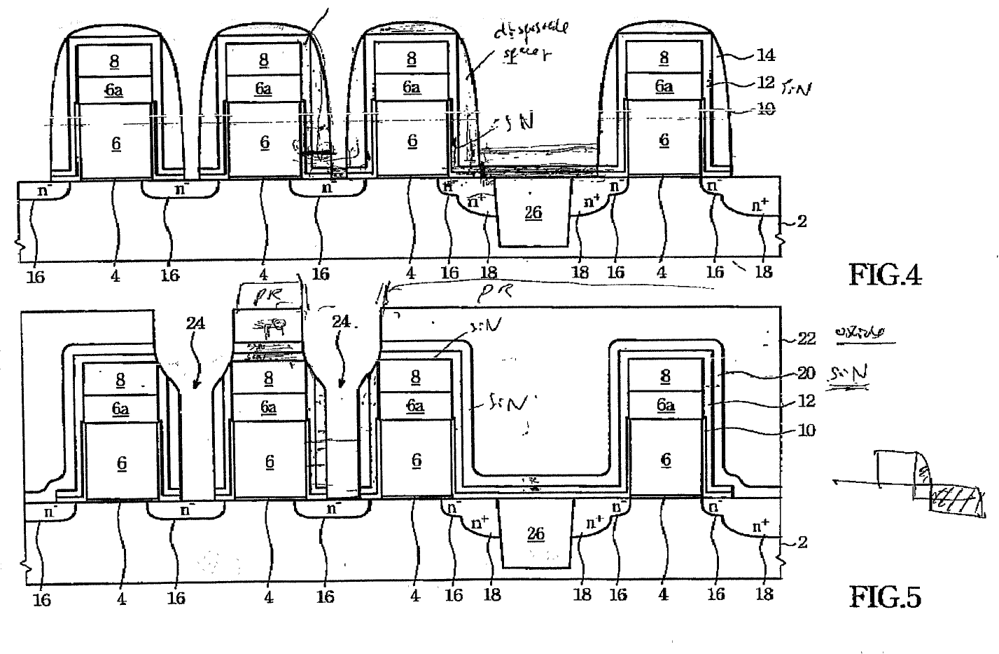

The present invention will be described in detail with reference to the drawings. The present invention provides a method to fabricate a self-align contact window. Further, the present invention can be used to improve the RC time delay problem, increase the spacing between gates and reduce the stress generated at the conventional nitride spacer corner. Referring to FIG. 4, a single crystal substrate 2 is P-type or N-type with [100] crystallographic orientation. Before constructing the devices, isolation region, such as field oxide regions or trench isolation regions will be previously formed on a semiconductor substrate for acting as isolations between devices. For example, a field oxide region is used and formed by using a pad oxide and silicon nitride as an oxidation barrier on the substrate. The silicon substrate is then oxidized in an oxygen ambient to form the field oxide regions. The thickness of the field, oxide region is about 4000-6000 angstroms. After that a conventional wet etch is used to remove the silicon nitride and the pad oxide. A so-called shallow trench isolation can also be used in lieu of the field oxide region.

A gate oxide layer 4, a polysilicon layer 6 are respectively deposited on the substrate 2. In general, the gate oxide 4 is formed by thermal process using a reaction gas including oxygen containment. Alternatively, the gate oxide layer 4 can be formed by using a low temperature CVD, such as plasma enhanced CVD using silane as a precursor. The gate oxide layer 4 may be formed using other known oxide chemical compositions and procedures. For example, the silicon oxide layer 10 can be formed using a chemical vapor deposition process, with a tetraethylorthosilicate (TEOS) source, at a temperature between about 300 to 450 degrees centigrade. Typically the polysilicon layer 6 is used as a gate of a MOS and formed by chemical vapor deposition to a thickness about 1000-2000 angstroms. As known in the art, metal silicide 6a can be optionally formed on the top of the polysilicon by well known technique.

A first silicon nitride layer 8 is then formed on the polysilicon layer to act as a cap layer or hard mask to protect the gate. Then, the gate oxide layer 4, the polysilicon layer 6 and the first silicon nitride layer 8 are etched to form a gate structure having a cap layer using a photoresist as an etching mask. The first silicon nitride layer 8 can be formed by LPCVD (low pressure chemi cal vapor deposition) process by reacting an excess of dichlorosilane with ammonia. The thickness of the the first silicon nitride layer 8 is between a range about 500-1000 angstroms.

Subsequently, a silicon dioxide layer 10 is optionally formed on the surface of the gate and substrate by thermal process. The thickness of the oxide 10 is about 50-150 angstroms. Any suitable thickness can be used. The purpose of forming the silicon oxide layer 10 is to provide a buffer for LDD) (lightly doped drain) implantation. An ion implantation is performed to form the LDD 16. Then, a thin liner layer 12 is deposited on the feature of the substrate 2. The thickness of the liner 12 is about 50 to 100 angstroms. The material for forming the linear layer 12 is composed of nitride. A material for a disposable spacer is successively deposited on the linear layer 12 after the formation of the linear layer 12. Preferably, the material for forming the spacer exhibits the characteristic of easily removable. One of the candidates is an oxide formed by TEOS. For example, the silicon oxide layer can be formed by using a chemical vapor deposition process, with a tetraethylorthosilicate (TEOS) source, at a temperature between about 300 to 450 degrees centigrade. The thickness of the TEOS is preferably about 200 to 800 angstroms, which can be adjustable by the device design requirement. An isotropical etching is carried out to etch the TEOS oxide thereby forming the spacer 14 attached on the side wall of the gate structure consisting of gate oxide 4, gate 6 and nitride cap 8, as shown in FIG. 4. The source and drain 18 is next created in the substrate 2 by ion implantation with higher dosage using the gate structure and spacer 14 as an implantation mask.

Turning to FIG. 5, after the source and drain 18 is formed, the disposable spacer 14 is then stripped. In a case, the spacer 14 is removed by wet dip technique using HF solution or BOE solution. The silicon nitride layer 12 will protect the STI and gate from being etching during the stripping and the whole structure will return to the original structure before depositing the TEOS. An optional step is next performed to form a borderless layer 20 on the surface of the first nitride layer 12. The borderless layer 20 is used to make sure the gate and the STI will not be etched during the procedure of SAC etching. If the thickness of the nitride layer 12 is thick enough, the borderless layer can be omitted. The material of the layer 20 can be nitride. The thickness of the borderless nitride layer 20 ranges from about 150 to 250 angstroms.

A dielectric layer 22 is formed on the gate structure to a thickness out 2500-4000 angstroms. The dielectric layer 22 can be composed of silicon dioxide, BPSG, SOG. Then, a photoresist (not shown) is patterned on the dielectric layer 22 to define the contact window area. The photoresist has an opening that is aligned to the substrate for contact. An etching with high selectivity between oxide and nitride is used to etch the dielectric layer 22. The dielectric layer 22 serves as an isolation layer for isolating the substrate 2 and the subsequent overlying layers that are used as interconnections or the like. The reaction gas of the highly selective etching between the layer 22 and the silicon nitride layer 12 and/or the borderless layer 20 are CO, C₄F₈, and CF₄. The etching rate of the silicon dioxide is faster than silicon nitride by using the etchant. The silicon nitride 20, 12 and silicon nitride cap layers 8 as etching barriers to form the contact hole 24 in the layer 22. Therefore, the highly selective etching process improves the accuracy of the contact hole.

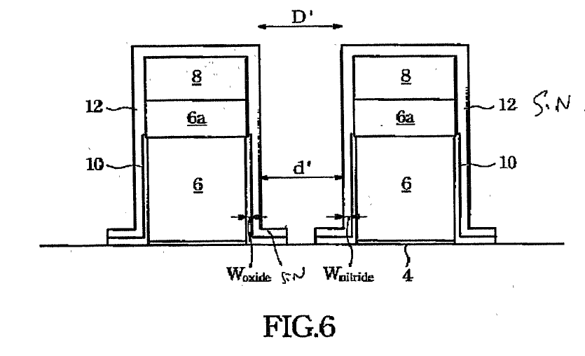

Since the disposable spacer 14 is removed prior to the SAC etching, the method will not narrow the spacing between the gates. The gap filling will be more easily than the prior art. The parasitic capacitor issue is improved by removing the spacer, and the stress generated by the conventional nitride spacer corner is also eliminated, simultaneously. Please turn to FIG. 6, the minimum spacing (indicated by d′) between spacers is approximately equal to D′-2 (W_{oxide}+W_{nitride}). Wherein D′ indicates the spacing between gates, W_{oxide} and W_{nitride} represent the widths of the oxide 10 and nitride 12, respectively. Assume that the dimension of the D′ is less than 0.19 micron meter, the widths of the W_{oxide} and W_{nitride} are about or ticker than 80-100 and 100-200, respectively. The aspect ratio of the contact (a ratio of a contact depth to width) is about 3.46 (0.45/0.13), which is better than the value of the prior art. Therefore, all of the problems generated by the prior art are solved by the method.

As is understood by a person skilled in the art, the foregoing preferred embodiment of the present invention is illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A method of fabricating a self-align contact (SAC) with a disposable spacer, said method comprising the steps of:
forming a gate oxide layer on a substrate;
forming a polysilicon layer on said gate oxide layer to act as a gate;
forming a first nitride layer on said polysilicon layer to act as a cap layer;
patterning said first nitride layer, said polysilicon layer and said gate oxide layer to form a gate structure;
forming a lightly doped drain (LDD) in said substrate;
forming a second nitride layer on a surface of said gate structure as linear layer;
forming said disposable spacer on side walls of said gate structure;
performing an ion implantation to form source and drain in said substrate using said gate structure and said disposable spacer as a mask;
removing said disposable spacer;
forming a dielectric layer on said liner, said gate structure and said substrate to serve as an isolation layer; and
patterning said dielectric layer to form a contact window in said dielectric layer and exposing a portion of said substrate.

2. The method of claim 1, further comprising forming an oxide layer on side wall of said gate and said substrate before forming said linear layer.

3. The method of claim 1, further comprising forming a metal salicide on said gate before forming said first nitride layer.

4. The method of claim 1, further comprising forming a borderless layer after forming said liner layer.

5. The method of claim 4, wherein said borderless layer comprises nitride.

6. The method of claim 1, wherein said disposable spacer comprises oxide.

7. The method of claim 7, wherein said disposable space is formed by chemical vapor deposition with a TEOS as reaction material.

8. The method of claim 7, wherein said disposable spacer is removed by HF solution.

9. The method of claim 7, wherein said disposable spacer is removed by BOE solution.

10. A self-aligned contact structure comprising:
transistors formed on a substrate;
a liner layer and a borderless layer encapsulated along a surface of said transistors;
a dielectric layer formed on said transistors, wherein said dielectric has holes formed therein, wherein a spacer between gates of said transistors being less than 0.19 micron, a thickness of said linear and said borderless layer are 80 to 100 and 100 to 200, respectively so as to form holes having a aspect ratio less than 3.46.

11. The, structure of claim 10, wherein said liner layer comprises nitride.

12. The structure of claim 10, wherein said borderless layer comprises nitride.
